(19) United States
(12) Patent Application Publication
(10) Pub. No.: US 2008/0163926 A1
(43) Pub. Date: Jul. 10, 2008

(54) Organic solar cell

(75) Inventors: Ping-Tsung Huang, Banciao City (TW); Hsiu-Chih Hsu, Fusing Township (TW); Chuan-Man Lan, Sansing Township (TW); Chao-Ting Chen, Jhongpu Township (TW)

Correspondence Address: KINNEY & LANGE, P.A., THE KINNEY & LANGE BUILDING, 312 SOUTH THIRD STREET, MINNEAPOLIS, MN, 55415-1002, US

(73) Assignee: Ritek Corporation, Hsinchu (TW)

(21) Appl. No.: 11/717,480

(22) Filed: Mar. 13, 2007

(30) Foreign Application Priority Data
Jan. 10, 2007 (TW) 96100974

(51) Int. Cl. H01L 31/00

(52) U.S. Cl. 136/261; 136/263

(57) ABSTRACT

An organic solar cell including a substrate, an organic solar cell device, at least one hydrophobic polymer layer and at least one metal layer is provided. The hydrophobic polymer layer and the metal layer are alternately stacked on the organic solar cell device. The hydrophobic polymer layer is used to prevent moisture from entering the organic solar cell device. The metal layer is used to prevent moisture and oxygen from entering the organic solar cell device. A method for forming an organic solar cell is also disclosed in the specification.

### RELATED APPLICATIONS

This application claims priority to Taiwan Application Serial Number 96100974, filed on Jan. 10, 2007, which is herein incorporated by reference.

### BACKGROUND

1. Field of Invention

The present invention relates to a structure of a solar cell. More particularly, the present invention relates to a package structure of an organic solar cell.

2. Description of Related Art

Nowadays, people deeply rely on fossil fuel to generate electric energy for daily life. However, pollution problems and gradual exhaustion of fossil fuel has pushed people to search for clean energy resources.

Solar energy is a clean and unfailing energy. Scientists exploit various solar cells with different materials and use them in electronic products. Researchers in academy and industry have paid a lot attention on organic solar cell recently because it contains an organic photoelectric conversion layer generally consisting of polymer materials, which can be prepared through a well-developed process such as coating or ink-jet printing.

However, the organic photoelectric conversion layer is sensitive to oxygen and moisture. The reaction of the organic photoelectric conversion layer with oxygen or moisture will reduce the power conversion efficiency and the life cycle of the organic solar cell. For the foregoing reasons, there is a need to develop an organic solar cell having a moisture and oxygen barrier layer.

### SUMMARY

An organic solar cell including a substrate, an organic solar cell device, at least one hydrophobic polymer layer and at least one metal layer is provided. The organic solar cell device includes a first electrode, an organic photoelectric conversion layer and a second electrode. The first electrode, the organic photoelectric conversion layer and the second electrode are located on the substrate in sequence. The hydrophobic polymer layer and the metal layer are alternately stacked on the organic solar cell device. The hydrophobic polymer layer is used to prevent moisture from entering the organic solar cell device. The metal layer is used to prevent moisture and oxygen from entering the organic solar cell device.

A method for manufacturing organic solar cell is provided. First, an organic solar cell device is formed on a substrate. After that, at least one hydrophobic polymer layer and at least one metal layer capable of removing oxygen and moisture are formed above the organic solar cell device. Each hydrophobic polymer layer and each metal layer are alternately stacked on the organic solar cell device, and one of the hydrophobic polymer layers is overlaid on the surface of the organic solar cell device.

### BRIEF DESCRIPTION OF THE DRAWINGS

These and other features, aspects, and advantages of the present invention will become better understood with regard to the following description, appended claims, and accompanying drawings where:

FIGS. 1˜2 show a cross-sectional view of the manufacturing process of the organic solar cell according to one embodiment of the present invention.

### DETAILED DESCRIPTION

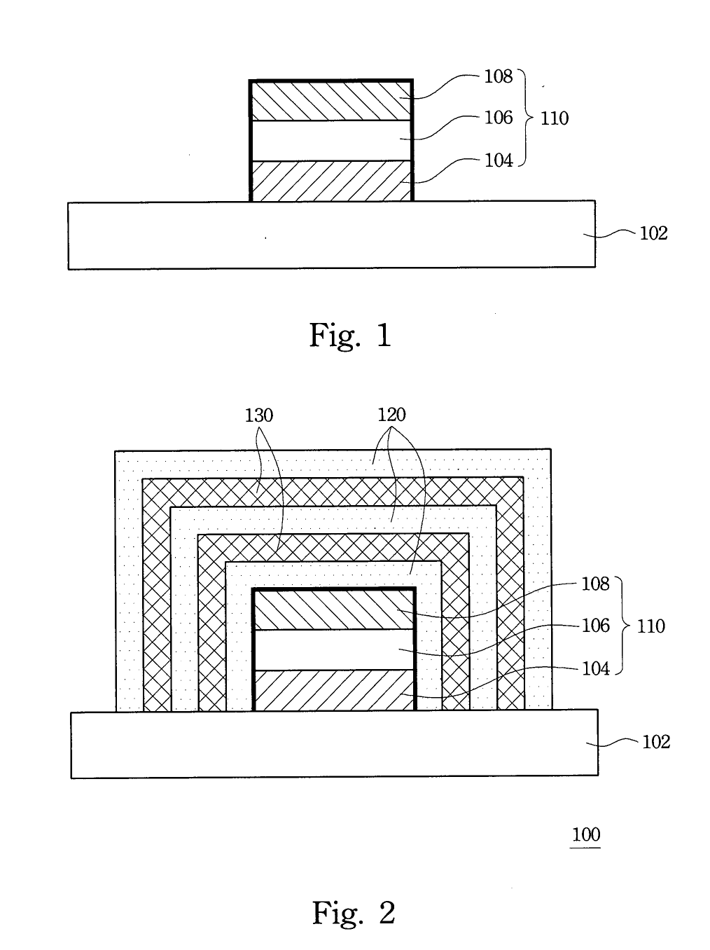

FIGS. 1˜2 show a cross-sectional view of the manufacturing process of the organic solar cell according to one embodiment of the present invention. Referring to FIG. 1, an organic solar cell device 110 is formed on a substrate 102. The substrate 102 can be a glass substrate or a flexible substrate such as a plastic substrate. The organic solar cell device 110 includes a first electrode 104, an organic photoelectric conversion layer 106 and a second electrode 108. The first electrode 104, the organic photoelectric conversion layer 106 and the second electrode 108 are located on the substrate 102 in sequence.

The organic photoelectric conversion layer 106 given above can be any practicable structure. For example, it can be a single/double layer including an organic donor material and an organic acceptor material. The organic donor material and the organic acceptor material either can be mixed in the single layer of the organic photoelectric conversion layer 106 or can be separately formed to double layers of the organic photoelectric conversion layer 106. The organic donor material given above can be poly(3-hexylthiophene) or poly(3-octylthiophene). The organic acceptor material can be C₆₀ or derivatives of C₆₀ such as 1-(3-methoxycarbonyl)propyl-1-phenyl[6,6]C₆₁ (PCBM). The organic photoelectric conversion layer 106 can be formed by spin coating or evaporation.

Referring to FIG. 1 again, the first electrode 104 can be an anode electrode such as an indium tin oxide (ITO) electrode. The second electrode 108 can be a cathode electrode such as an aluminum electrode or a silver electrode. The first electrode 104 and the second electrode 108 can be formed by evaporation or sputtering. The forming method of the first electrode 104 and the second electrode 108 is determined by the type of electrode material. The anode electrode and the cathode electrode are exchangeable, for example, the first electrode 104 can be the cathode electrode and the second electrode 108 can be the anode electrode. A hole transporting layer (not shown in the drawing) is selectively coated or evaporated on the area between the anode electrode and the organic photoelectric conversion layer 106. The material of the hole transporting layer can be PEDOT:PSS (poly(3,4-ethylenedioxythiophene)poly(styrene sulfonate)). The organic solar cell device 110 given above is not limited to the structure, material and the forming method described above.

Referring to FIG. 2, a hydrophobic polymer layer 120 is further formed on the organic solar cell device 110 to prevent moisture from entering the organic solar cell device 110. The thickness of the hydrophobic polymer layer 120 is ranged from 10 angstroms to 10 micrometers. The forming method of the hydrophobic polymer layer 120 may includes two steps. First, a reactant such as a monomer or an oligomer of the hydrophobic polymer layer 120 is formed on the organic solar cell device 110. The monomer or the oligomer can be formed by spin coating, ink-jet printing or screen printing. The monomer or the oligomer of the hydrophobic polymer layer 120 has a hydrophobic functional group or a hydrophobic molecular fragment and can be a photo-curable material, a heat-curable material or a self-curable material. After that, the monomer or the oligomer can be light-irradiated (UV light), heated, or aged for a period of time to form the hydrophobic polymer layer 120.

The reactant of the hydrophobic polymer layer 120 can have a hydrophobic molecular fragment, such as polydimethylsiloxanes, and a polymerization functional group located on terminals of the hydrophobic molecular fragment. The polymerization functional group given above can be vinyl group, epoxy group, methacrylate group, or acrylate group. A catalyst or an initiator is added to the reactant together with light or heat treatment to carry out polymerization reaction. Besides, the hydrophobic polymer layer 120 can be formed by two different reactants. For example, one reactant contains both hydrophobic molecular fragment and at least two amine groups, while the other reactant contains at least two epoxy groups. The amine group on one reactant reacts with the epoxy group on the other reactant to form the hydrophobic polymer layer 120.

The reactant of the hydrophobic polymer layer 120 described above may be vinyl terminated polydimethylsiloxanes, vinyl terminated diphenylsiloxane-dimethylsiloxane copolymer, epoxypropoxypropyl terminated polydimethyl siloxanes, methacryloxypropylmethylsiloxane-dimethylsiloxane copolymers, (3-acryloxy-2-hydroxypropoxypropyl)methylsiloxanedimethylsiloxanecopolymer.

In addition to the forming method of the hydrophobic polymer layer 120 given above, another method is provided. First, a hydrophobic polymer is dissolved in a solvent to reduce the viscosity of the hydrophobic polymer. After that, the hydrophobic polymer solution is formed on the organic solar cell device 110 by spin coating, ink-jet printing or screen printing. Finally, the solvent of the hydrophobic polymer solution is further removed to form the hydrophobic polymer layer 120.

Referring to FIG. 2 again, a metal layer 130 is further formed on the hydrophobic polymer layer 120. The thickness of the metal layer 130 is ranged from 10 angstroms to 10 micrometers. The metal layer 130 is capable of removing oxygen or moisture entering the organic solar cell because the metal layer 130 can react with oxygen and moisture. Besides, the metal oxide layer formed by the reaction given above can prevent moisture and oxygen from continuously permeating into the organic solar cell device 110. The metal layer 130 can be an aluminum layer, a silver layer or a silver-aluminum alloy layer. The metal layer 130 can be formed by sputtering, evaporation, or electron beam evaporation.

After the metal layer 130 is formed on the hydrophobic polymer layer 120, another hydrophobic polymer layer 120 and another metal layer 130 can be formed on the metal layer 130 in sequence. The hydrophobic polymer layer 120 is formed on the outmost surface of the multi-layered structure alternately consisting of the hydrophobic polymer layer 120 and the metal layer 130 to prevent moisture and oxygen from entering the organic solar cell device 110. Each hydrophobic polymer layer 120 may consists material same as/different from the material of another hydrophobic polymer layer 120. Each metal layer 130 may also consists material same as/different from the material of another metal layer 130. For example, one metal layer 130 can be an aluminum layer while another metal layer 130 can be a silver layer. Besides, to increase the efficiency of the organic solar cell 100, a reflective layer (not shown in drawing) can be formed above the organic solar cell device 110. When the incident light from the substrate 102 enters the organic solar cell 100 and passes through the organic solar cell device 110, the reflective layer is able to reflect the light back to the organic solar cell device 110. However, the metal layer 130 may be used instead of the reflective layer to reflect the light back to the organic solar cell device 110 if it is provided with light-reflective ability.

The structure alternately consisting of the hydrophobic polymer layer and the metal layer is capable of preventing moisture and oxygen from entering the organic solar cell device. Therefore, life cycle and stability of the moisture/oxygen-sensitive organic solar cell can be increased Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An organic solar cell, comprising:
a substrate;
an organic solar cell device located on the substrate, wherein the organic solar cell device comprises:
a first electrode located on the substrate;
an organic photoelectric conversion layer located on the first electrode; and
a second electrode located on the organic photoelectric conversion layer;
at least one hydrophobic polymer layer located above the organic solar cell device, wherein one of the hydrophobic polymer layers is overlaid on the surface of the organic solar cell device to prevent moisture from entering the organic solar cell device; and
at least one metal layer located above the organic solar cell device to prevent moisture and oxygen from entering the organic solar cell device, wherein each hydrophobic polymer layer and each metal layer are alternately stacked on the organic solar cell device.

2. The organic solar cell of claim 1, wherein each metal layer is selected from a group consisting of an aluminum layer, a silver layer and a silver-aluminum alloy layer.

3. The organic solar cell of claim 1, wherein the thickness of each metal layer is ranged from 10 angstroms to 10 micrometers.

4. The organic solar cell of claim 1, wherein the thickness of each hydrophobic polymer layer is ranged from 10 angstroms to 10 micrometers.

5. The organic solar cell of claim 1, wherein the material of each hydrophobic polymer layer is selected from a group consisting of a photo-curable material, a heat-curable material and a self-curable material.

6. The organic solar cell of claim 5, wherein the photo-curable material is an ultra-violet curable material.

7. The organic solar cell of claim 1, wherein one of the hydrophobic polymer layers is located on the outmost surface of the multi-layered structure alternately consisting of the hydrophobic polymer layer and the metal layer.

8. The organic solar cell of claim 1, further comprising a reflective layer, above the organic solar cell device, the reflective layer being capable of reflecting the light passing through the organic solar cell device back to the organic solar cell device.

9. The organic solar cell of claim 1, wherein the substrate is a glass substrate or a flexible substrate.

10. The organic solar cell of claim 1, wherein the second electrode is a cathode electrode when the first electrode is an anode electrode, or the first electrode is a cathode electrode when the second electrode is an anode electrode.

11. A method for manufacturing an organic solar cell, comprising
forming an organic solar cell device on a substrate; and
forming at least one hydrophobic polymer layer and at least one metal layer used for removing moisture and oxygen, wherein each hydrophobic polymer layer and each metal layer are alternately stacked on the organic solar cell device, and one of the hydrophobic polymer layers is overlaid on the surface of the organic solar cell device.

12. The organic solar cell manufacturing method of claim 11, wherein the forming method of the hydrophobic polymer layer comprising:
forming a monomer or an oligomer of the hydrophobic polymer layer on the organic solar cell device or the metal layer; and
carrying out a curing reaction for the monomer or the oligomer to form the hydrophobic polymer layer.

13. The organic solar cell manufacturing method of claim 12, wherein the monomer or the oligomer of the hydrophobic polymer layer is formed on the organic solar cell device or the metal layer by spin coating, ink-jet printing or screen printing.

14. The organic solar cell manufacturing method of claim 12, wherein the curing reaction of the monomer or the oligomer is selected from a group consisting of photo-curing reaction, heat-curing reaction and self-curing reaction.

15. The organic solar cell manufacturing method of claim 11, wherein the forming method of the hydrophobic polymer layer comprises:
dissolving a hydrophobic polymer in a solvent to form a hydrophobic polymer solution;
coating the hydrophobic polymer solution on the organic solar cell device or the metal layer; and
removing the solvent from the hydrophobic polymer solution to form the hydrophobic polymer layer.

16. The organic solar cell manufacturing method of claim 11, wherein the forming method of each metal layer is selected from a group consisting of sputtering method, evaporation method and electron beam evaporation method.
